(19) United States
(12) Patent Application Publication
(10) Pub. No.: US 2021/0307177 A1
(43) Pub. Date: Sep. 30, 2021

(54) SYSTEMS AND METHODS FOR MANUFACTURING

(71) Applicant: AVERATEK CORPORATION, Santa Clara, CA (US)

(72) Inventors: Shinichi Iketani, Sunnyvale, CA (US); Michael Vinson Riley, Sunnyvale, CA (US)

(21) Appl. No.: 17/344,288

(22) Filed: Jun. 10, 2021

Related U.S. Application Data
(62) Division of application No. 16/845,856, filed on Apr. 10, 2020.
(60) Provisional application No. 62/833,211, filed on Apr. 12, 2019.
(60) Provisional application No. 62/833,223, filed on Apr. 12, 2019.
(60) Provisional application No. 62/886,086, filed on Aug. 13, 2019.
(60) Provisional application No. 62/894,190, filed on Aug. 30, 2019.
(60) Provisional application No. 62/896,488, filed on Sep. 5, 2019.

(51) Int. Cl. H05K 3/18; C25D 5/02; C23C 18/16; C25D 5/48

(52) U.S. Cl. CPC H05K 3/188; H05K 3/184; C25D 5/48; C23C 18/1689; C23C 18/1605; C25D 5/022

(57) ABSTRACT

Various inventions are disclosed in the microchip manufacturing arts. Conductive pattern formation by semi-additive processes are disclosed. Further conductive patterns and methods using activated precursors are also disclosed. Aluminum laminated surfaces and methods of circuit formation therefrom are further disclosed. Circuits formed on an aluminum heat sink are also disclosed. The inventive subject mater further discloses methods of electrolytic plating by controlling surface area of an anode.

This application is a divisional of, and claims the benefit of priority to, U.S. patent application Ser. No. 16/845,856, filed Apr. 10, 2020, which claims the benefit of U.S. Provisional Patent No. 62/833,211, filed Apr. 12, 2019, U.S. Provisional Patent No. 62/833,223, filed Apr. 12, 2019, U.S. Provisional Patent No. 62/886,086, filed Aug. 13, 2019, U.S. Provisional Patent No. 62/894,190, filed Aug. 30, 2019, and U.S. Provisional Patent No. 62/896,488, filed Sep. 5, 2019, each of which is incorporated by reference in its entirety herein.

### FIELD OF THE INVENTION

The field of the invention relates to methods and systems for manufacturing conductive patterns.

### BACKGROUND

The following description includes information that may be useful in understanding the present invention. It is not an admission that any of the information provided herein is prior art or relevant to the presently claimed invention, or that any publication specifically or implicitly referenced is prior art.

('211) As conductive patterns such as electrical circuits and chips continue to miniaturize, and the complexity and intricacy of the circuits continues to increase, improvements are needed in the art of electrical circuit manufacturing to meet market demands effectively and efficiently. In general, plating conductive material to polyimide or other substrates is known in the art. For example, WO1998019858 to Missele teaches depositing a layer of silver onto a substrate, followed by plating a conductive material to the silver layer. However, Missele does not provide for shaping the plated conductive material and does not teach a finished product having only substrate and the intended circuit pattern, both of which are desirable features for manufacturing processes.

All publications identified herein are incorporated by reference to the same extent as if each individual publication or patent application were specifically and individually indicated to be incorporated by reference. Where a definition or use of a term in an incorporated reference is inconsistent or contrary to the definition of that term provided herein, the definition of that term provided herein applies and the definition of that term in the reference does not apply.

Efforts have been made to further shape or design the pattern of conductive material in an electric circuit. For example, GB892451 to Wolf appears to teach depositing silver on a substrate, depositing a plating resist over the silver in the pattern of a circuit, plating a metal to the exposed silver surface, removing the resist layer, and rendering the exposed silver inert. However, the teachings of Wolf are wasteful, and do not provide for efficient use of material, selecting the thickness of silver or metallic layers, or controlling the conductivity of the plated metal.

Thus regarding conductive pattern formation by semi-additive process, there is still a need for improved methods and systems for efficiently manufacturing conductive patterns such as electric circuits with silver and conductive layers of specific thickness and conductivity.

('223) As electrical circuits are integrated into more every-day items, efficiencies in manufacturing such circuits for flexible applications are needed. Introducing new or improved methods of manufacture that reduce use of expensive materials, or reduce process times, are of great value. For example, U.S. Pat. No. 7,981,508 to Sharma et al teaches depositing a palladium precursor from a solvent onto a substrate, and further decomposing the palladium precursor to activated palladium to act as a catalyst for further plating of conductive materials. Of note, the '508 patent appears to teach against decomposing the palladium precursor in a manner or method that would damage or melt the underlying substrate. While '508 appears to achieve a reduction in costly materials, it fails to reduce steps in manufacturing processes or otherwise reduce process time.

Efforts have been made to otherwise reduce manufacturing steps or streamline the manufacturing process. For example, US Publication No. 2019/0019736 to Schrauben appears to teach using a laser to create a trench on substrate and deposit material into the trench from a donor film via laser-induced forward transfer, as well as depositing a precursor into a trench on the substrate and activating the precursor using a laser. While the '736 publication appears successful at sharing resources between manufacturing steps, it fails to provide a consistent, thin layer of deposited material in a trench on a substrate for further manufacturing processes. Further, the '736 publication apparently fails to combine the forming of trenches on a substrate with the activation, or deposition and activation, of a precursor or catalyst material in the trench.

Thus regarding conductive patterns and methods for making thereof, there is still a need for improved methods and systems for simultaneously forming a trench on a substrate and activating a deposited precursor in the trench, and optionally depositing the precursor materials in the trench in the same step when manufacturing conductive patterns.

('086) Improvements in the quick, quality, and economical manufacture of fine circuitry are constantly sought, with much improvement left in the field. For example, it is known to use laminates to increase the bind or adhesion of conductors plated to dielectric materials, but the process for depositing such laminates is often wasteful and costly as they rely upon copper supported laminate. Further, while embedding conductive layers in the dielectric material of a substrate is known to improve the durability of the resulting circuits, there is a need to improve the durability of conductive layers that are present on a surface of a dielectric material. Further, while efforts have been made to improve the adhesion or binding of conductive layers to the surface of substrates by marking the surfaces, such efforts have been unsuccessful in stable roughness conditions on the substrate surface, leading to low quality and inconsistent conductivity.

Thus regarding aluminum laminated surfaces and methods of circuit formation, there is still a need for improved methods and systems for lowering the costs and improving the durability and quality of manufacturing conductive layers on substrates.

('190) One problem in the electronic circuit arts is dissipating heat generated by the circuits. It is known to dissipate heat by using a heat sink, for example a metal structure with one or more flat surfaces to ensure good thermal contact with the electronic components to be cooled, and an array of comb or fin like protrusions to increase the surface contact with the air, and thus the rate of heat dissipation. It is also known to use adhesives to bind the heat sink to the circuit. However, adhesives are known to reduce thermal conductivity between the heat sink and the circuit, and can reduce the structural strength of the circuit and heat sink assembly.

Thus regarding circuits formed on an aluminum heat sink, there is still a need for improved methods and systems for improving heat dissipation in electrical circuits, for example increasing thermal conductivity between a circuit and a heat sink to enable use of thinner dielectric materials.

('488) Another problem in designing and producing electric circuits is uniformly depositing conductive material in a simple process to intricately designed circuit boards with regions of the board having different or disparate concentrations or density of circuit patterns across the board. While U.S. Pat. No. 6,521,102 to Dordi (“Dordi”) attempts to use perforated anodes to introduce a uniform flow of electrolyte from the anode to the cathode in electrolytic deposition, Dordi fails to provide a uniform deposition of conductive material on the circuit board, where the circuit board includes regions of varying density of circuit pattern.

Thus regarding methods of electrolytic plating by controlling surface area of an anode, there is still a need for improved methods, systems, and devices for providing substantially uniform plating of conductor to a circuit board in a circuit pattern in a simple, low cost, and low waste application, where the circuit board includes regions of varying concentration or surface density of circuit patterns.

### SUMMARY OF THE INVENTION

('211) Regarding conductive pattern formation by semi-additive process, the inventive subject matter provides apparatus, systems and methods for manufacturing a portion of a conductive pattern. A first material, typically silver or a silver alloy, is deposited on a substrate, preferably to a thickness of 0.3 nm or more. The conductivity of the first material (e.g., silver) is critical, as depositing thin layers having sufficient conductivity reduces material cost and increases efficiency of the process. While multi step processes are known, for example depositing an electroless plating catalyst (e.g., palladium), followed by electroless plating a layer of copper to a sufficient conductivity for electrolytic plating of material in a further process, some aspects of the inventive subject matter contemplate a simplified process. A plating resist layer is formed in a pattern (e.g., negative circuit pattern) over at least part of the first material, yielding an exposed portion of the first material. Viewed from another perspective, the exposed portion of the first material is in the shape of a desired conductive pattern, or at least a portion of the pattern.

A second material, typically conductive or at least one of cobalt, rhodium, iridium, nickel, palladium, platinum, copper, silver, gold, or an alloy thereof, is plated over the exposed portion of the first material, preferably electroless plating, electrolytic plating, or some combination thereof. In some embodiments, the second material is deposited by electroless plating, followed by a third material (at least one of cobalt, rhodium, iridium, nickel, palladium, platinum, copper, silver, gold, or an alloy thereof) deposited on the second material by electrolytic plating. The plating resist layer is then removed (e.g., dissolved, etched, etc), and the portion of the first material not plated with the second material is further removed or rendered non-conductive. Viewed from another perspective, the portion of the first material that is not covered by the second material is removed. Preferably, the first material deposited on the substrate has a conductivity of at least 10⁵ S/m, and more or less of the first material can be deposited on the substrate to increase or decrease the conductivity of the layer.

In some embodiments, the first material is deposited via a precursor ink having a metal carboxylate and a solvent. It is also contemplated the first material is deposited on the substrate as a precursor having one or more organo-metals. The organo-metal, or plurality thereof, is one of a metal carboxylate, a metal chelate, a metal colloid, or combinations thereof. Metal carboxylates are preferably silver carboxylates having less than seven carbons. Metal chelates or metal colloids are preferably soluble in an aqueous or mixed aqueous solution (e.g., aqueous and organic solution). The precursor alternatively, or additionally, includes at least one non-chelating ligand, for example at least one Nitrogen (N)-donor, Oxygen (O)-donor, Phosphorous (P)-donor, Arsenic (As)-donor, Sulfur (S)-donor ligand, or combinations thereof, that are soluble in either aqueous or mixed aqueous solutions. In preferred embodiments, the precursor is soluble in a mixed aqueous solution. A surfactant can also be added to the precursor when the precursor is in solution.

Conductive patterns are also contemplated, including a substrate, a layer of a first material (e.g., silver, silver alloy, etc), and a layer of a second material (e.g., cobalt, rhodium, iridium, nickel, palladium, platinum, copper, silver, gold, an alloy thereof, etc). The first layer is at least 0.3 nm thick, preferably greater than 10 nm thick, more preferably greater than 30 nm thick, yet more preferably more than 50 nm thick. Likewise the second material can be deposited as a single coat (e.g., at least 300 nm deposited via electroless plating, electrolytic plating, or combination thereof), or can be deposited in multiple coats to reach desired thickness (e.g., at least 200 nm, at least 300 nm, at least 400 nm deposited via electroless plating, electrolytic plating, or combination of electroless plating followed by electrolytic plating, etc). Viewed from another perspective, in some embodiments the second material layer comprises materials (different or the same) that are deposited by different deposition methods, for example electroless plating followed by electrolytic plating.

Further methods of manufacturing a conductive pattern are contemplated. A plating resist layer is deposited over a layer of first material (e.g., silver, silver alloy, etc). A conductive pattern is formed in the plating resist layer (e.g., laser ablation, mechanical ablation, etc), such that the conductive pattern exposes a portion of the first material. A second material is plated over the exposed portion of the first material in the conductive pattern, and the plating resist layer is removed (e.g., solvent, laser ablation, mechanical ablation, etc). Portions of the first material that are not covered or plated by the second material are also removed or rendered non-conductive. The layer of first material typically resides on a substrate, and in preferred embodiments the first material is deposited on the substrate to a thickness of greater than 0.3 nm, or to a conductivity of at least 10⁵ S/m, or both.

('223) The inventive subject matter provides apparatus, systems and methods for manufacturing conductive patterns on a substrate. A precursor carrying a material is deposited on a substrate. A beam, preferably an energy beam or laser, is directed toward a portion of the precursor on the substrate, such that the material contacted by the beam is activated (e.g., catalytic, etc) and a portion of the substrate proximal to the activated material (e.g., adjacent or below) is removed by the beam (e.g., ablated, excised, etc), preferably occurring simultaneously or within less than 3, 2, 1, 0.1, or 0.01 seconds. A first conductive material (e.g., cobalt, rhodium, iridium, nickel, palladium, platinum, copper, silver, gold, or an alloy thereof) is plated to the activated material (e.g., palladium, electroless plating catalyst, etc), preferably by electroless plating, though electrolytic plating or combination of plating is also contemplated.

The precursor typically comprises a metal carboxylate, for example a carboxylate with 2, 3, 4, 5, 6, or more than 7 carbons, and a metal selected from at least one of Pd, Pt, Au, Ag, Rh, Cu, Ni, or Co. Thus, the activated material is typically elemental Pd, Pt, Au, Ag, Rh, Cu, Ni, or Co, though it is contemplated that precursors having more than one metal, or precursors having different metal carboxylates, can also be used, resulting in more than one or a variety of active catalyst metals. As mentioned above, plating conductive materials (e.g., first conductive material) typically involves electroless plating conductive materials to the activated material (preferably affixed to the substrate, e.g., surface of a trench), which is preferably followed by further electrolytic plating another conductive material (e.g., different or the same as the first) to the conductive material. Viewed from another perspective, a thin layer of active catalyst in the trench enables a first conductive material to be electroless plated to the trench, which enables electrolytic plating of conductive materials to the first conductive material, reducing the amount of expensive materials required or harsh chemical washes used to otherwise plate conductive layers in precise patterns.

It is contemplated that appropriate beams have a resolution of less than 100 μm on the substrate, and are capable of forming trenches less than 50 μm, 25 μm, 15 μm, 5 μm, 1 μm, 500 nm, 250 nm, 100 nm, 50 nm, 40 nm, 30 nm, 20 nm, 10 nm, or less than 5 nm wide, and up to 25 μm, 15 μm, 5 μm, 1 μm, 500 nm, 300 nm, 200 nm, 150 nm, 100 nm, 50 nm, or 10 nm deep. It is further contemplated that appropriate lasers have a resolution such that the material in the precursor is activated, deposited, or both, on the substrate in bands no more than 5 nm, 10 nm, 20 nm, 30 nm, 40 nm, 50 nm, 100 nm, 250 nm, 500 nm, 1 μm, 5 μm, 15 μm, 25 μm, 50 μm, or 100 μm wide.

While the beam is preferably a laser (e.g., a CO2 laser, an excimer laser, a UV laser, a YAG laser, etc), it is contemplated that an electron beam or a plasma beam can be used, alternatively or in combination, to remove substrate and activate or deposit the material on the substrate, or both. In preferred embodiments, the beam is pulsed at no more than 1 millisecond intervals, preferably no more than 1 ns intervals to activate the material, deposit the material, or both, and remove a portion of the substrate proximal to the activated or deposited material. Beams in the inventive subject matter, including lasers, have a wavelength of between 120 nm and 10 μm. In some embodiments, it is advantageous to remove a portion of the precursor from the substrate by applying a rinsing solution (e.g., organic solvent, precursor solvent, carboxylate, etc) after the step of directing the beam. Where the beam includes, in whole or in part, a pulsed laser, it is contemplated the laser (e.g., wavelength between 120 nm and 10 μm) has a peak pulse of less than 100 W, and in some embodiments the average power of the pulsed laser is less than 100 W.

Removing the portion of substrate proximal to the activated material using the beam typically forms a recessed pattern in the substrate, where the activated material is preferably affixed. Recessed patterns are typically no more than 25 μm, more preferably no more than 10 μm, 5 μm, or 1 μm. The first conductive material is plated in the recessed pattern, for example via electroless plating. The substrate is typically made up of one of a plastic, a glass, a ceramic, silicon, a silicon based material, or a combination or composite thereof. Preferably, at least the portion of the substrate that is contacted by the beam is made up of one of a plastic, a glass, a ceramic, silicon, a silicon based material, or a combination or composite thereof.

Further methods of manufacturing a conductive pattern on a substrate are contemplated. A substrate is coated (at least partially) with a precursor having a metal carboxylate. In some embodiments, the precursor is spray coated onto the substrate, for example a precursor having inks (e.g., metallic ink, metallic carboxylate ink, etc) dissolved in an organic solvent is preferably spray coated onto the substrate. The metal caroboxylate is typically complexed with another compound, preferably an electron donor. For example, the metal carboxylate is preferably complexed with any one of a primary amine, a secondary amine, a tertiary amine, a carbonyl, a sulfonyl, a nitryl, or a phosphoryl. It should be appreciated that the inventive subject matter contemplates a substance comprising a single type or multiple types of metal carboxylates, where the single (or multiple different types) of metal carboxylates are each complexed with the same type of compound (e.g., electron donor, same type of electron donor, a primary amine, a secondary amine, a tertiary amine, a carbonyl, a sulfonyl, a nitryl, a phosphoryl, etc), or at least two (or at least three, or at least four) metal carboxylates are each complexed with different types of compounds (e.g., different electron donors, different types of electron donors, a primary amine, a secondary amine, a tertiary amine, a carbonyl, a sulfonyl, a nitryl, a phosphoryl, etc).

A beam is used to simultaneously (i) remove a portion of the substrate to form a recess in the substrate, and (ii) deposit a metal from the metal carboxylate as an electroless plating catalyst in the recess (e.g., depositing and activating the metal). A first conductive material is then plated to the electroless plating catalyst, for example via electroless plating, electrolytic plating, or a combination thereof. An organic solvent optionally removes the precursor from the substrate before plating the first conductive material. In some embodiments, it is favorable to plate a second conductive material to the first conductive material, for example via electrolytic plating following electroless plating of the first conductive material.

('086) The inventive subject matter provides conductive layers and methods for manufacture conductive layers, for example as part or all of an electric circuit. Methods of manufacturing a conductive layer include forming a surface topography on a surface of a substrate by laminating a layer of aluminum to the surface of the substrate. The layer of aluminum is removed from the substrate, and a catalyst is deposited over the surface topography of the substrate. A dielectric layer is then formed over the catalyst in a negative pattern of part (or most, or all) of the conductive layer. The part of the conductive layer is then deposited to the catalyst in the negative pattern.

In some embodiments, the conductive pattern can be formed on the opposite side of the substrate, either sequentially or simultaneously with the forming of the conductive pattern discussed above. For example, a second surface topography on a surface on the opposite side of the substrate is formed by laminating a layer of aluminum to the surface on the opposite side of the substrate. The layer of aluminum is removed from the opposite side of the substrate, and a catalyst is deposited over the surface topography on the opposite side of the substrate. A dielectric layer is then formed over the catalyst in a negative pattern of part (or most, or all) of the conductive layer to be formed on the opposite side of the substrate. The conductive layer is then deposited to the catalyst in the negative pattern on the opposite side of the substrate, and dielectric layer and portions of the catalyst covered by the second plating resist layer.

It is contemplated that additional conductive patterns can be formed on the same side of the substrate, or on opposite sides of the substrate under the inventive subject matter. Further, where multiple conductive patterns are formed on the substrate, the aluminum layers, surface topographies, lamination methods, aluminum removal methods, catalysts, dielectric layers, negative patterns, or conductors in the conductive layer can be the same, different, or some combination thereof.

Contemplated methods of manufacturing conductive layers further include forming a surface topography on a surface of a substrate by laminating a layer of aluminum to the surface of the substrate. The layer of aluminum is then removed from the substrate (e.g., mechanically, chemically, etc). A catalyst is then deposited over the surface topography of the substrate, and a seed layer is formed over the first surface, for example by electrochemical deposition. A plating resist layer is then formed over (at least part of) the seed layer in a negative pattern of part (or most, or all) of the conductive layer. Part of the conductive layer is then deposited (e.g., via electrolytic deposition of a conductor) to the seed layer in the negative pattern. The plating resist layer, along with the portions of the seed layer and the catalyst covered by the plating resist layer, are then removed, either sequentially or simultaneously.

Methods of the inventive subject matter for manufacturing conductive layers include forming conductive layers on opposite sides, or disparate parts, of a common substrate. For example, a surface topography on the surface on the opposite side of the substrate is formed by laminating a layer of aluminum to the surface. The layer of aluminum is then removed from the opposite side of the substrate, and a catalyst is deposited over the surface topography on the opposite side of the substrate. A seed layer is then formed over the surface on the opposite side (e.g., via electrochemical deposition), and a plating resist layer is formed over the seed layer in a negative pattern of part (or most, or all) of the conductive layer. Part of the conductive layer is then deposited to the seed layer in the negative pattern (e.g., via electrolytic deposition). The plating resist layer, and the portions of the seed layer and the catalyst covered by the plating resist layer, are then removed.

Conductive layers manufactured by described processes are contemplated as within the inventive subject matter.

Devices of the inventive subject matter include cladded laminates having a topography on a dielectric substrate. An aluminum film has a surface that includes the topography. Another aluminum film also has a surface that includes the topography. A dielectric substrate is sandwiched between the topography-bearing surfaces of the two aluminum films, such that a surface of the dielectric substrate acquires the topography. The aluminum films can include a laminate layer (e.g., at the topographical surface), and can be sacrificial (e.g., easily removed mechanically or chemically).

The inventive subject successfully lowers the cost of producing stable, durable, and high quality conductive layers and circuits by using sacrificial layers of roughened aluminum to imbue substrate surfaces with highly stable, controllable, and consistent roughness conditions, in some embodiments in conjunction with laminate layers.

('190) The inventive subject matter provides apparatus, systems and methods for forming a conductive layer with improved heat dissipation and improved adherence between the conductive layer and a heat sink. A layer of aluminum oxide is deposited over a surface of aluminum. A catalyst precursor that includes a metal carboxylate is deposited over the layer of aluminum oxide, and the catalyst precursor is cured to form a catalyst layer. The catalyst layer is then used to deposit the conductive layer, for example to the catalyst layer.

The metal carboxylate of the catalyst precursor is typically at least one of palladium, platinum, gold, silver, or rhodium, or combinations thereof. In some embodiments, the catalyst precursor further comprises a second metal carboxylate, for example different than the first metal carboxylate. Preferably, the catalyst precursor is cured chemically, thermally, photothermally, or photochemically, or sequential or substantially simultaneous combinations thereof. Additionally or alternatively, the catalyst precursor is cured by corona, plasma, incoherent, or coherent radiation or sequential or substantially simultaneous combinations thereof.

The conductive layer typically includes at least one of copper, nickel, gold, silver, alloys thereof, or combinations thereof. In some embodiments, the catalyst layer is an electroless plating catalyst. A conductive metal can further be electrolytically plated to the conductive layer, for example where the conductive metal is copper, nickel, gold, silver, or alloys thereof.

The layer of aluminum oxide is typically between 50 nm and 500 um thick, 50 nm and 400 um thick, 50 nm and 300 um thick, 50 nm and 200 um thick, or 50 nm and 100 um thick. Likewise, the layer of aluminum oxide and the catalyst layer typically have a combined are thickness no more than 500 um thick, 400 um thick, 300 um thick, 200 um thick, or 100 um thick. In some embodiments the surface of aluminum is a dielectric substrate. Preferably, the combined thickness of the catalyst and aluminum oxide is reduced or minimized to increase thermal conductivity between the conductor layer and the aluminum layer.

Further methods of manufacturing a conductive layer with a heat sink are contemplated. A layer of a heat sink material is deposited on a substrate (e.g., dielectric, etc), and a layer of an oxide of the heat sink material is further deposited over the layer of heat sink material. A catalyst layer is deposited over the layer of the oxide, and the catalyst layer is used to deposit the conductive layer onto the heat sink. It should be appreciated that improving the heat dissipation of the conductive layer allows use of thinner or less substrate (e.g., dielectric).

In some embodiments, forming the catalyst layer over the oxide layer includes (i) depositing a catalyst precursor over the oxide layer and (ii) curing the catalyst precursor to form the catalyst layer, for example curing chemically, thermally, photothermally, photochemically, or sequential or substantially simultaneous combinations thereof. Additionally or alternatively, the catalyst precursor is cured by corona, plasma, incoherent, or coherent radiation, or sequential or substantially simultaneous combinations thereof. The catalyst precursor preferably includes a metal carboxylate of at least one of palladium, platinum, gold, silver, or rhodium, or combinations thereof.

The heat sink material preferably includes aluminum (or alloys thereof), but can also be another anodizing metal, example nonferrous metals (e.g., magnesium, titanium, etc), or combinations thereof. Preferably the oxide layer comprises aluminum oxide, but can include oxides of other anodizing metals or combinations thereof. The oxide layer is typically between 50 nm and 500 um thick, 50 nm and 400 um thick, 50 nm and 300 um thick, 50 nm and 200 um thick, or 50 nm and 100 um thick.

The conductive layer is typically electroless plated, using the catalyst layer. The conductive layer is typically at least one of copper, nickel, gold, silver, or alloys thereof. A further conductive metal (e.g., copper, nickel, gold, silver, alloys thereof, the same as the conductive layer, etc) is electrolytic plated to the conductive layer in some embodiments.

('488) The inventive subject matter further provides apparatus, systems and methods for electrolytic plating a conductor from an anode onto a cathode pattern across a substrate surface. A first region of the cathode pattern that has a first surface density of cathode is identified, and a second region of the cathode pattern that has a second surface density of cathode is also identified, sequentially or substantially simultaneously.

An anode is formed to plate the conductor to the cathode pattern. The anode has a first region with a surface area, and a second region with a surface area. The first region of the anode approximates (e.g., precisely matches, 90%, 80%, or 70% matches, precisely overlaps, 120%, 110%, 100%, 90%, 80%, or 70% overlaps, combinations thereof, etc) the shape of the first region of the cathode pattern. Likewise, the second region of the anode approximates the shape of the second region of the cathode pattern (e.g., substantially the same degree of approximation as the first region, at least the same degree of approximation as the first region, within 1%, 5%, or 10% degree of approximation of the first, at least 1%, 5%, 10%, or 15% increased degree of approximation as the first region; no more than 1%, 5%, 10%, or 15% reduced degree of approximation as the first region, etc).

The anode is then aligned such that the first region of the anode is proximal (e.g., preferably substantially overlapping, precisely overlapping, within 1%, 2%, 3%, 4%, 5%, 6%, 7%, 8%, 9%, 10%, or 15% of precisely overlapping, etc) to the first region of the cathode pattern (e.g., the first region of the anode and the first region of the cathode pattern are preferably separated by no more than 5 cm, 10 cm, 20 cm, 30 cm, 40 cm, 50 cm, or 100 cm, no more than 50%, 60%, 70%, 80%, 90%, 100%, 110%, or 120% of the greatest dimension of the first or second region of the anode (e.g., length, width), etc).

Likewise, the second region of the anode is proximal to the second region of the cathode pattern. In some embodiments, the anode or the regions of the anode are substantially parallel to the cathode, though it is contemplated that either the anode, regions of the anode, or the cathode are tilted askew such that portions of the anode, regions of the anode, or the cathode are closer to the corresponding surface of its counterpart. The conductor is then electrolytically plated from the anode to from the cathode pattern.

The first surface area of the anode is typically proportional to the first surface density of cathode. For example, where first surface area of the anode is X and first surface density of cathode is Y, and X is proportional to Y, then where first surface density of cathode is 2Y, first surface area of the anode is 2X. Likewise, the second surface area of the anode is preferably proportional to the second surface density of cathode. In some embodiments, the first surface density of cathode is greater than the second surface density of cathode. The first region of the anode can also have openings (e.g., holes) with density D1 (e.g., first region of anode has area A, B openings in the first region, giving density of openings D1=B/A). The second region of the anode can likewise include openings with density D2. In some embodiments, D1 is less than D2, though it is contemplated that D1 can be substantially equal to D2.

In some embodiments, forming the anode includes forming openings in the first region of the anode to create the first surface area, and forming openings in the second region of the anode to create the second surface area. Viewed from another perspective, where the first region of the anode has area A, openings formed in the first region have cumulative area B, the first surface area is equal to A minus B. The shape of the openings in the first region are typically at least one of a triangle, a quadrilateral, a rhombus, a rectangle, a square, a diamond, a pentagon, a hexagon, a heptagon, an octagon, an oval, an ellipse, a circle, a reversed broadened image of the cathode pattern, abstract, random, or a regular or irregular combination thereof. Preferably, the openings in the first region are arranged in a pattern, in some embodiments the pattern is regular and approximates the shape of the cathode pattern in the first region.

Some embodiments further include identifying a third region of the cathode pattern with a third surface density of cathode. A third surface area in the third region is formed on the anode, such that the third region of the anode approximates the shape of the third region of the cathode pattern (e.g., mirror image, approximate mirror image, shape with 120%, 115%, 110%, 105%, 95%, 90%, 85%, or 80% overlap of the cathode pattern, etc). The anode is then aligned such that the third region of the anode is proximal to the third region of the cathode pattern.

The anode is typically either the conductor or insoluble (e.g., insoluble in an electrolyte solution, etc). Preferably electrolytic plating includes using an electrolyte solution with high flow between the anode and the cathode (e.g., flow rate that saturates, 120% saturates, 110% saturates, 95% saturates, 90% saturates, 85% saturates, or 80% saturates the cathode pattern with conductor, etc). A shield can also be placed between the first region of the cathode pattern and the first region of the anode, where the shield typically includes openings (e.g., hole, channel, etc) between the first region of the anode and the first region of the cathode. The openings preferably approximate the shape of the first region of the cathode pattern, and more preferably the dimensions of the openings on the shield, or at least a portion of the openings, is substantially uniform. However, regular or irregular patterns of openings in the shield, of uniform, partially uniform, or disparate dimensions, are also contemplated.

In some embodiments, the first region of the cathode pattern is approximately the same size as the second region of the cathode pattern. Likewise, the first region of the anode is approximately the same size as the second region of the anode. However, in preferred embodiments the cathode pattern is divided into sections with consistent or substantially homogenous distribution of cathode, with the size of each section dependent on the size of homogenous regions of the cathode pattern. Likewise, the anode can be divided into matching regions, where each region is sized dependent on the size of homogenous regions of the cathode pattern.

Further methods are contemplated where a circuit board has a circuit pattern (e.g., cathode pattern) with regions of differing concentration or surface density of circuit pattern across the circuit board. A corresponding anode has regions of differing surface area of anode, such that each region of differing surface density of circuit pattern has a corresponding, substantially overlapping region on the anode having a surface area that is proportional to the surface density of the circuit pattern in the corresponding region. The anode is aligned such that the corresponding regions of the anode and the circuit board are aligned (e.g., matched regions of anode are aligned with matched regions of the circuit board), and the circuit pattern is electrolytically plated.

Electrolytic plating apparatus and systems are contemplated including an anode having a first region with a first surface area and a second region with a second surface area. The first region of the anode approximates (e.g., substantially, within 20%, 15%, 10%, 5%, or 1% of true, etc) the footprint of a first region of a substrate having a first surface density of a conductor pattern. Preferably, the first region of the anode has a first surface area proportional to the first surface density of the conductor pattern.

The second region of the anode likewise approximates the footprint of a second region of the substrate having a second density of a conductor pattern. The second region of the anode preferably has a second surface area proportional to the second surface density of the conductor pattern. In some embodiments, the first region of the anode is approximately the same size as the second region of the anode, though the regions of the anode can be sized and dimensioned to substantially match regions of the conductor pattern having homogenous density or concentration of pattern. Generally, the first surface area of the anode is different than the second surface area of the anode.

The first region of the anode (preferably the second as well) has openings (e.g., through holes, gaps, channels, slits) arranged in a pattern. The pattern can be regular or irregular, and preferably approximates the shape of the conductor pattern in the first region. The shape of the openings in the first region is at least one of a triangle, a quadrilateral, a rhombus, a rectangle, a square, a diamond, a pentagon, a hexagon, a heptagon, an octagon, an oval, an ellipse, a circle, a reversed broadened image of the conductor pattern in the first region of the conductor pattern, abstract, random, or a regular or irregular combination thereof. Preferably the first region of the anode (more preferably the entire anode) is either insoluble or a metal conductor for electrolytic plating to the conductor pattern.

In some embodiments, a computer is used to scan or otherwise analyze the surface features of a circuit board to determine the surface area or density required for a circuit design. The computer uses the surface area of the circuit design to design an anode pattern having proportional anode to plate the circuit design.

Various objects, features, aspects and advantages of the inventive subject matter will become more apparent from the following detailed description of preferred embodiments, along with the accompanying drawing figures in which like numerals represent like components.

### BRIEF DESCRIPTION OF THE DRAWINGS

FIGS. 1A to 1E depict steps in a manufacturing process of the inventive subject matter.

FIGS. 2 and 3 depict steps in another manufacturing process of the inventive subject matter.

FIGS. 4A and 4B depict steps in a further manufacturing process of the inventive subject matter.

FIGS. 5A and 5B depict steps in yet another manufacturing process of the inventive subject matter

FIG. 6 depicts a conductor assembly of the inventive subject matter.

FIGS. 7A and 7B depict plating assemblies of the inventive subject matter.

FIG. 8 another plating assembly of the inventive subject matter.

FIG. 9A depicts a circuit board produced by steps of the inventive subject matter.

FIG. 9B depicts an anode used in manufacturing processes of the inventive subject matter.

FIG. 9C depicts further anodes used in manufacturing processes of the inventive subject matter.

### DETAILED DESCRIPTION

Various methods, systems, and devices for manufacturing conductive circuits are disclosed.

('211) Regarding conductive pattern formation by semi-additive process, the present invention relates to methods, systems and devices for manufacturing a portion of an electric circuit. The principles and operations for such methods and systems, according to the present invention, may be better understood with reference to the accompanying description and drawings.

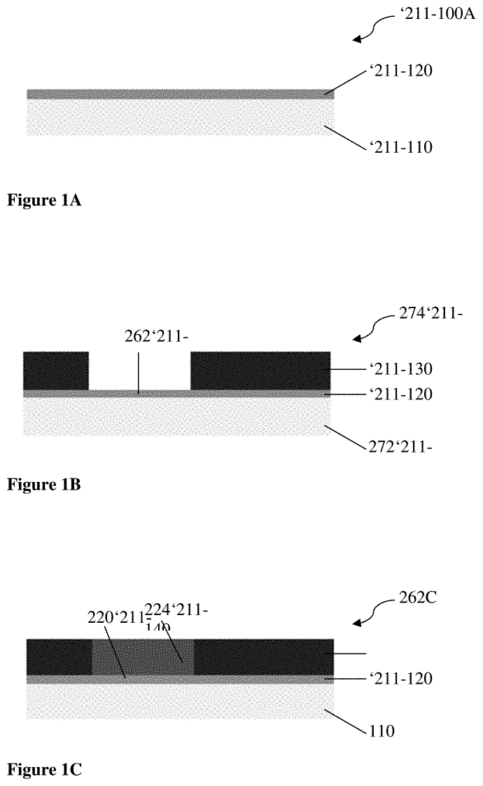

FIG. 1A depicts step '211-100A of a manufacturing process of the inventive subject matter. Silver layer '211-120 is deposited onto substrate '211-110, typically to a thickness of 0.3 nm, 0.6 nm, less than 1 nm, less than 5 nm, less than 10 nm, or more. For instance, silver layer '211-120 is made from a silver carboxylate solution. The applied silver carboxylate solution is dried and deposits silver carboxylate over the substrate. The silver carboxylate thermally or chemically reduced, or both, to form a very thin (e.g., less than 30 nm, 20 nm, 15 nm, 10 nm, 5 nm, 1 nm, 0.6 nm, or no more than 0.3 nm, etc) and uniform silver layer '211-120 over the substrate surface.

FIG. 1B depicts step '211-100B of a manufacturing process of the inventive subject matter. Plating resist '211-130 is deposited over silver layer '211-120, and a negative pattern of the circuit is formed by exposing portions of the silver layer, such as exposed portion '211-122. In some embodiments plating resist '211-130 is deposited in the form of the negative pattern, but it is also contemplated that plating resist '211-130 is deposited as a solid layer, and the negative pattern is formed by removing portions of plating resist '211-130 in a separate step (e.g., laser ablation, mechanical ablation, etc).

FIG. 1C depicts step '211-100C of a manufacturing process of the inventive subject matter. Conductive material '211-140 (e.g., cobalt, rhodium, iridium, nickel, palladium, platinum, copper, silver, gold, an alloy thereof, etc) is plated onto exposed portion '211-122 of silver layer '211-120. Conductive material '211-140 cannot plate onto portions of silver layer '211-120 that are blocked by plating resist '211-130.

FIG. 1D depicts step '211-100D of a manufacturing process of the inventive subject matter. Plating resist '211-130 has been removed (e.g., solvent, laser ablation, mechanical ablation, etc), leaving behind conductive material '211-140 plated to exposed portion '211-122 of silver layer '211-120, as well as the rest of silver layer '211-120 deposited on substrate '211-110.

FIG. 1E depicts step '211-100E of a manufacturing process of the inventive subject matter. The portions of silver layer '211-120 that were not covered or plated to conductive material '211-140 have also been removed (e.g., mechanical ablation, etching, etc), leaving behind substrate '211-110, previously exposed portion '211-122 of silver layer '211-120, and conductive material '211-140 plated to the previously exposed portion '211-122 of silver layer '211-120. It should be appreciated that conductive material '211-140 forms the pattern of an electrical circuit.

('223) The present invention further relates to methods, systems and devices for manufacturing conductive patterns on a substrate. The principles and operations for such methods and systems, according to the present invention, may be better understood with reference to the accompanying description and drawings.

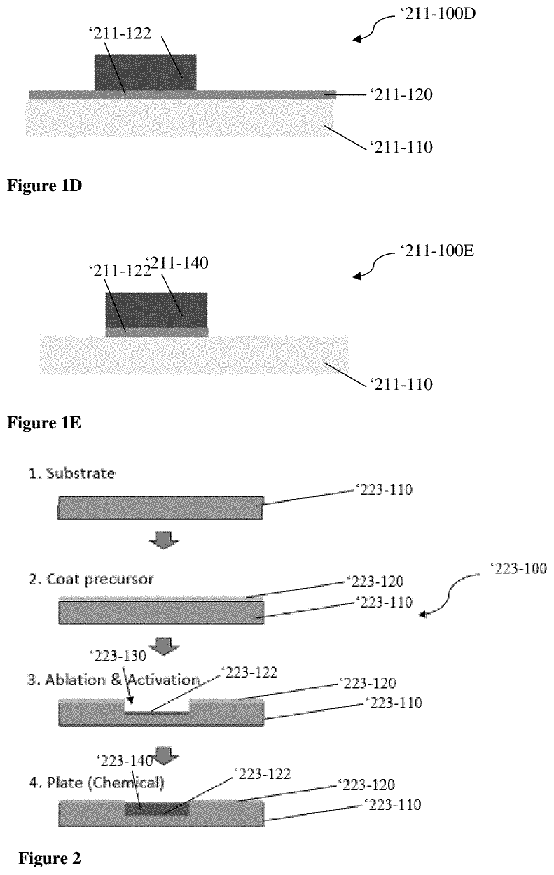

FIG. 2 depicts schematic '223-100 of a manufacturing process of the inventive subject matter. A surface of substrate '223-110 is at least partially coated by precursor '223-120, which carries a metal carboxylate, preferably a carboxylate or at least one of Pd, Pt, Au, Ag, Rh, Cu, Ni, or Co. A beam, preferably a laser, is then directed at precursor '223-120 and substrate '223-110 in the shape of a pattern. Where the beam contacts precursor '223-120 and substrate '223-110, the substrate is removed (e.g., ablated, excised, etc) forming a recess or trench (e.g., recess '223-130), and the metal from the metal carboxylate is activated (e.g., activated metal '223-122) and affixed to a surface of recess '223-130. Conductive material '223-140 is then plated to activated metal '223-122 (e.g., via electroless plating to activated metal '223-122, via electroless plating to activated metal '223-122 followed by electrolytic plating to the conductive material, etc) to form a conductive pattern.

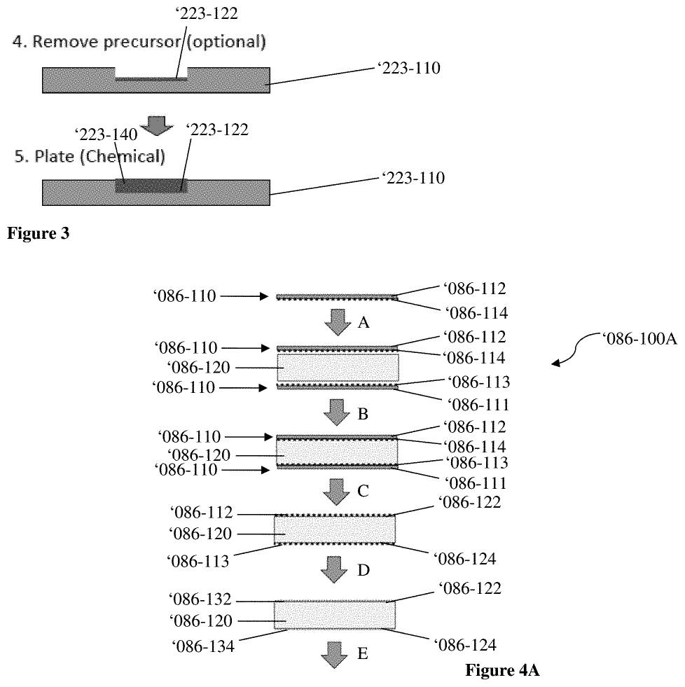

FIG. 3 depicts an optional step in the manufacturing process of schematic '223-100. After recess '223-130 is formed and the beam has activated the metal in precursor '223-120 to activated metal '223-122, an organic solvent, for example a carboxylate solvent or a solvent present in precursor 120, is optionally used to rinse excess or remaining precursor 120 from substrate 110. Conductive material 140 is then plated to activated metal 122 (e.g., electroless plating catalyst) as described in FIG. 1.

('086) The inventive subject matter provides conductive layers and methods for manufacture conductive layers, for example as part or all of an electric circuit. Methods of manufacturing a conductive layer include forming a surface topography on a surface of a substrate by laminating a layer of aluminum to the surface of the substrate. The layer of aluminum is removed from the substrate, and a catalyst is deposited over the surface topography of the substrate. A dielectric layer is then formed over the catalyst in a negative pattern of part (or most, or all) of the conductive layer. The part of the conductive layer is then deposited to the catalyst in the negative pattern.

Typically, the surface of the layer of aluminum interfacing (e.g., abutting, coupled to, adhered to, connected to, etc) with the surface of the substrate includes the surface topography. For example, the surface topography is present on the aluminum surface, and when laminated or pressed to the substrate surface, the surface topography is acquired by the substrate surface, in mirrored/imprinted form. The layer of aluminum is typically removed chemically or mechanically. In some embodiments, laminating the layer of aluminum to the substrate is done by at least one of heat, pressure, or adhesion. The surface topography can also a laminate film (e.g., resin).

The catalyst is typically at least one of a catalyst for electroless metal deposition, a sputtered catalyst, an aqueous treatment catalyst, for instance traditional tin palladium colloidal catalyst and ionic palladium catalyst, or an ink metal catalyst. The portions of the catalyst covered by the first dielectric layer are removed chemically, mechanically, thermally, photonically or combination processes of two or more thereof. The conductor of the conductive layer is preferably deposited to the catalyst in the negative pattern by electroless plating. The electrolytic plating can be used when the electrolessly deposited metal has enough conductivity. The substrate is preferably a porous dielectric, a semi-porous dielectric, or a non-porous dielectric. The surface topography is preferably a regular or irregular pattern of at least one of cones, spheroids, cylinders, cubes, tetrahedrons, pyramids, pits, ridges, crags, valleys, or waves. In some embodiments, the first surface topography has a maximum arithmetic average roughness (Rmax) of less than 15 microns, preferably less than 7.5 microns. Preferably, the surface topography has an arithmetic average roughness (Ra) less than 5 microns, preferably less than 2.5 microns, more preferably 1.0 micron. The layer of aluminum is typically at most 1000 microns thick.

In some embodiments, the conductive pattern can be formed on the opposite side of the substrate, either sequentially or simultaneously with the forming of the conductive pattern discussed above. For example, a second surface topography on a surface on the opposite side of the substrate is formed by laminating a layer of aluminum to the surface on the opposite side of the substrate. The layer of aluminum is removed from the opposite side of the substrate, and a catalyst is deposited over the surface topography on the opposite side of the substrate. The second dielectric layer is then formed over the catalyst in a negative pattern of part (or most, or all) of the conductive layer to be formed on the opposite side of the substrate. The conductive layer is then deposited to the catalyst in the negative pattern on the opposite side of the substrate and portions of the catalyst covered by the second dielectric layer.

It is contemplated that additional conductive patterns can be formed on the same side of the substrate, or on opposite sides of the substrate under the inventive subject matter. Further, where multiple conductive patterns are formed on the substrate, the aluminum layers, surface topographies, lamination methods, aluminum removal methods, catalysts, dielectric layers, negative patterns, or conductors in the conductive layer can be the same, different, or some combination thereof.

Contemplated methods of manufacturing conductive layers further include forming a surface topography on a surface of a substrate by laminating a layer of aluminum to the surface of the substrate. The layer of aluminum is then removed from the substrate (e.g., mechanically, chemically, etc). A catalyst is then deposited over the surface topography of the substrate, and a seed layer is formed over the first surface, for example by electrochemical deposition. A plating resist layer is then formed over (at least part of) the seed layer in a negative pattern of part (or most, or all) of the conductive layer. Part of the conductive layer is then deposited (e.g., via electrolytic deposition of a conductor) to the seed layer in the negative pattern. The plating resist layer, along with the portions of the seed layer and the catalyst covered by the plating resist layer, are then removed, either sequentially or simultaneously. The plating resist layer is preferably removed chemically, mechanically, thermally, photonically or combination processes or two or more thereof.

Methods of the inventive subject matter for manufacturing conductive layers include forming conductive layers on opposite sides, or disparate parts, of a common substrate. For example, a surface topography on the surface on the opposite side of the substrate is formed by laminating a layer of aluminum to the surface. The layer of aluminum is then removed from the opposite side of the substrate, and a catalyst is deposited over the surface topography on the opposite side of the substrate. A seed layer is then formed over the surface on the opposite side (e.g., via electrochemical deposition), and a plating resist layer is formed over the seed layer in a negative pattern of part (or most, or all) of the conductive layer. Part of the conductive layer is then deposited to the seed layer in the negative pattern (e.g., via electrolytic deposition). The plating resist layer, and the portions of the seed layer and the catalyst covered by the plating resist layer, are then removed.

Complete or partial conductive layers manufactured by the described processes, in whole or in part, are contemplated as within the inventive subject matter.

Devices of the inventive subject matter include cladded laminates having a topography on a dielectric substrate. An aluminum film has a surface that includes the topography. Another aluminum film also has a surface that includes the topography. A dielectric substrate is sandwiched between the topography-bearing surfaces of the two aluminum films, such that a surface of the dielectric substrate acquires the topography. The aluminum films can include a laminate layer (e.g., at the topographical surface), and can be sacrificial (e.g., easily removed mechanically or chemically). The cladded laminate can further include a resin and/or a reinforcement, for example in the laminate layer. Preferably, the resin includes at least one of epoxy, polyimide, cyanate ester, hydrocarbon, fluorinated hydrocarbon, bismaleimide triazine resin, or a combination of two or more thereof. The reinforcement preferably includes at least one of fabric, paper, particle, chopped fiber, or a combination of two or more thereof. The aluminum film (or films) is (are) preferably less than 5000 microns thick, and can be of the same or different thicknesses. The topography is preferably a regular or irregular pattern of at least one of cones, spheroids, cylinders, cubes, tetrahedrons, pyramids, pits, ridges, crags, valleys, or waves.

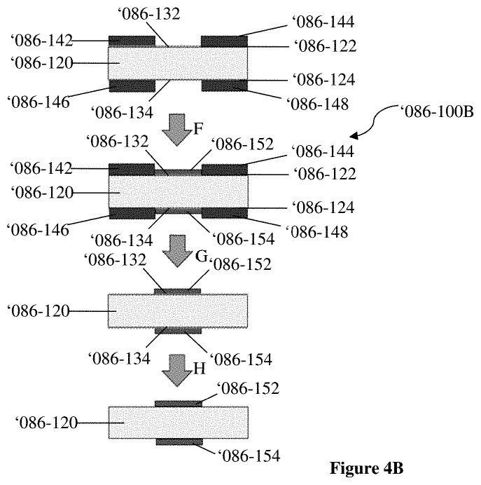

FIG. 4A depicts part of workflow '086-100A of an embodiment of the inventive subject matter. Workflow '086-100A includes steps A, B, C, D, and E, and is continued on FIG. '086-1B in workflow '086-100B with steps F, G, and H. Starting materials for workflow '086-100A includes aluminum film '086-110, which includes aluminum layer '086-112 with roughened surface '086-114. In some embodiments, roughened surface '086-114 can further have a release treatment. Also roughened surface '086-114 can further include a laminate film. In step A, substrate '086-120 is sandwiched between two pieces of aluminum film '086-110, with roughened surfaces '086-113 and '086-114 facing toward substrate '086-120.

In step B, the two pieces of aluminum film '086-110 are pressed against substrate '086-120, which impresses the topography of roughened surfaces '086-113 and '086-114 into the surfaces of substrate '086-120. The substrate '086-120 can be used B-stage prepreg and it can be cured during lamination of the two pieces of aluminum film '086-110. In embodiments where roughened surfaces '086-113 and '086-114 further include a laminate film (e.g., resin), aluminum films are further heated or laminated to secure the laminate film to the surface of the substrate.

In step C, aluminum layers '086-111 and '086-112 of aluminum films '086-110 are removed, for example mechanically (e.g., peeled off) or chemically (e.g., etching). This leaves roughened surfaces '086-122 and '086-124 of the substrate, which bear a substantial (or complete) impression of roughened surfaces '086-113 and '086-114 of aluminum films '086-110. Again, in embodiments where aluminum films '086-110 further include a laminate film at roughened surfaces '086-113 and '086-114, the laminate remains on roughened surfaces '086-122 and '086-124 of substrate '086-120. A treatment (e.g., treatment with grafting agent, coupling agent, microetching agent, or combination of two or more thereof) for final conductor adhesion improvement can be applied over the roughened surfaces '086-122 and '086-124 of substrate '086-120.

In step D, seed layers '086-132 and '086-134 (e.g., conductive layers for electrolytic deposition) are deposited on roughened surfaces '086-122 and '086-124 of substrate '086-120. The seed layer can be formed by electroless deposition, spattering, PVD or CVD. In case of electroless deposition, a catalyst deposition is conducted prior to electroless deposition. The catalyst can be selected from Pd, Pt, Au, Ag, Rh or mixture of two or more thereof. The catalyst deposition can be used a process with tin or other metal colloid, ionic chelate or organometal. In embodiments where a laminate layer is in roughened surfaces '086-122 and '086-124, it is contemplated that the laminate layer improves the deposition of a seed layer on roughened surfaces '086-122 and '086-124 of the substrate. However, in all cases it is contemplated that the roughened nature of roughened surfaces '086-122 and '086-124 of substrate '086-120 improves deposition of seed layers '086-132 and '086-134, especially in comparison to deposition on substrates with smooth or non-roughened surfaces. Step E continues into FIG. '086-1B.

FIG. 4B depicts workflow '086-100B of an embodiment of the inventive concept, which continues from workflow '086-100A of FIG. '086-1A. In step E, plating resist layers '086-142, '086-144, '086-146, and '086-148 are deposited over seed layers '086-132 and '086-134 in a pattern that exposes seed layers '086-132 and '086-134 in a negative image of a desired conductive layer. In some embodiments, the plating resist layer is formed by depositing the plating resist layer, and then removing portions in the shape of the negative patter, for example by etching, ablation, photo exposure, dry film photoresist, etc. In step F, conductive layers '086-152 and '086-154 (e.g. copper for high conductivity) are plated to seed layers '086-132 and '086-134 in the shape of the negative pattern made by the plating resist layers. In preferred embodiments, the conductive layers are deposited by electrolytic plating.

In step G, plating resist layers '086-142, '086-144, '086-146, and '086-148 are removed (e.g., etching, ablation, photo exposure, etc), and in step H, portions of seed layers '086-132 and '086-134 previously covered by the plating resist layers are removed (e.g., chemically, mechanically, etc). The final product of workflows '086-100A and '086-100B is a substrate with a conductive pattern on two sides, with increased durability and adhesive of the conductive patterns to the substrate by virtue of the roughened surface of substrate '086-120, and in some embodiments by the presence of a laminate layer. As aluminum is of lower cost than other metal materials suited for making film, is easier to work with, and can easily be removed from a substrate surface (e.g., chemically, mechanically), the inventive subject matter is a vast improvement over known methods.

While FIGS. 4A and 4B are depicted treating the substrate on two opposite sides, it should be appreciated that treating two separate (e.g., disparate) portions of a substrate on the same side, or treating a portion of one side of the substrate with by the teachings herein is further contemplated as within the inventive subject matter.

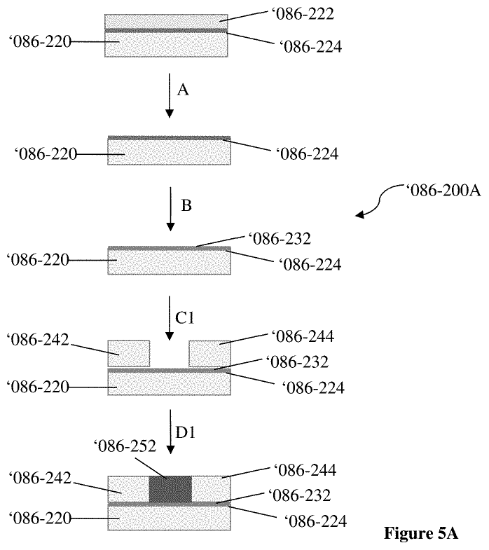

FIG. 5A depicts workflow '086-200A, which includes steps A, B, C1, and D1. Starting materials for step A include substrate '086-220, aluminum layer '086-222, and roughened surface layer '086-224, having the surface topography from aluminum layer '086-222 transferred onto roughened surface '086-224. The surface of aluminum layer '086-222 has a roughened topography, which creates an impression of the roughened topography on the surface of substrate '086-220. This starting material is preferably derived by laminating an aluminum clad laminate comprising aluminum layer '086-222 having a roughened surface at an interface/surface '086-224 onto substrate '086-220, for example using heat and pressure. Also roughened surface '086-224 can be transferred during a lamination process utilizing B-stage resin of substrate '086-220.

In step A, aluminum layer '086-222 is removed from substrate '086-220, leaving behind surface topography of aluminum layer '086-222 on roughened surface '086-224 on the substrate '086-220. In step B, a particle form of catalyst '086-232 (e.g., electroless plating catalyst, sputtered catalyst, metal ink, etc) is deposited over roughened surface layer '086-224. In some embodiments, roughened surface layer '086-224 improves the quality of depositing and binding of catalyst '086-232 to the surface of substrate '086-220. Moreover, the roughened surface of substrate '086-220 impressed by the roughed surface of aluminum layer '086-222 improves the deposition and binding of catalyst '086-232 to the surface of the substrate.

In step C1, dielectric materials '086-242 and '086-244 are deposited over catalyst '086-232 in a negative pattern forming at least part (or most, or all) of a desired pattern for a conductive layer (e.g., circuit), leaving catalyst '086-232 exposed where the conductive layer is desired. In step D1, conductor '086-252 (e.g., copper) is plated to portions of catalyst '086-232 in the negative pattern created by dielectric materials '086-242 and '086-244. An electrolytic plating can be applied over electroless metal deposited over catalyst '086-232. This process can be repeated to create multilayer conductive patterns. The final product of workflow '086-200A is a substrate with a conductive pattern that has increased durability, forming intricate, micron and sub-micron scale conductive patterns in trenches, cavities, or holes with greatly improved resistance to physical damage during the conductive pattern formation process, and adhesion of the conductive pattern to the substrate by virtue of the roughened surface of substrate '086-220 at roughened surface layer '086-224.

FIG. 5B depicts workflow '086-200B, which is an alteration of workflow '086-200A, with modification beginning at step C2 and proceeding with steps D2, E, F, and G. In step C2, particle or film format catalyst '086-232 of the substrate '086-220 preceding step C1 in workflow '086-200A is used to deposit conductor '086-262 to roughened surface '086-224 (e.g., via electroless deposition). In step D2, plating resist layers '086-272 and '086-274 are formed over conductor '086-262, leaving a negative pattern exposing conductor '086-262 in the shape of the desired conductive layer (e.g., part of a circuit, most of a circuit, all of a circuit, etc).

In step E, conductive layer '086-282 is plated to conductor '086-262 (e.g., electrolytic plating) forming the desired pattern for a conductive layer. In step F, plating resist layers '086-272 and '086-274 are removed, and in step G, portions of conductor '086-262 not covered by conductive layer '086-282 are further removed. Optionally, palladium or other catalyst residue under removed conductor '086-262 removing process can be applied. It helps further surface finish process utilizing electrochemical metal deposition. The final product of workflow '086-200B is a substrate with a conductive pattern that has increased durability and adhesion of the conductive pattern to the substrate by virtue of the roughened surface of substrate '086-220 and the presence of roughened surface layer '086-224.

('190) Regarding circuits formed on an aluminum heat sink, the present invention further relates to methods, systems and devices for forming a conductive layer with improved heat dissipation and improved adherence between the conductive layer and a heat sink, as well as reducing the thickness of thickness of a base dielectric layer.

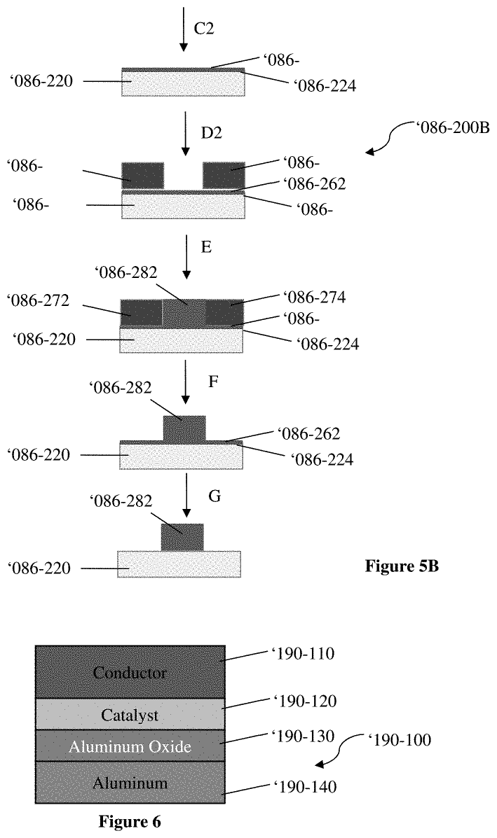

FIG. 6 depicts a conductor composite '190-100 of the inventive subject matter. The base layer '190-140 is substantially (preferably entirely) of aluminum, though other anodizing metals or contemplated. In some embodiments, the base layer is further set on, adhered to, or embedded in a dielectric material (not pictured). Aluminum oxide layer '190-130 (or oxide of another anodized metal) is formed over aluminum layer '190-140, preferably between 50 nm and 500 μm thick. Catalyst layer '190-120 is then deposited over oxide layer '190-130. Preferably, the combined thickness of catalyst layer '190-120 and aluminum oxide layer '190-130 is minimized to improve thermal conductivity between the aluminum layer and the conductive layer. Catalyst layer '190-120 is then used to deposit conductive layer '190-110, for example by electroless deposition. Further conductive materials can then be plated to the conductive layer, for example by electrolytic deposition.

('488) Regarding methods of electrolytic plating by controlling surface area of an anode, the present invention further relates to methods for electrolytic plating a conductor from an anode onto a cathode pattern across a substrate surface, and systems and devices for such plating.

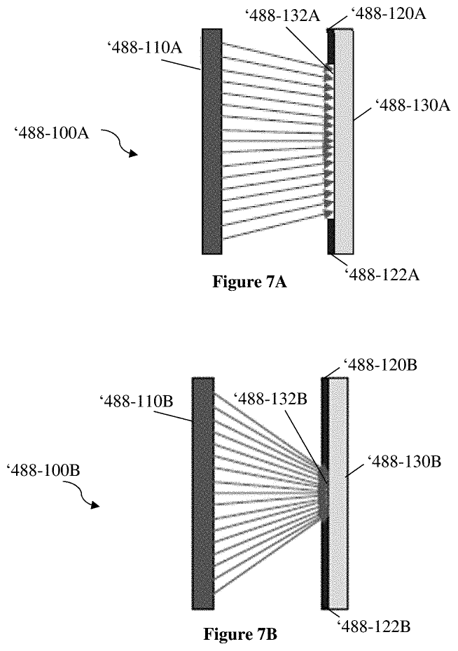

FIG. 7A depicts plating assembly '488-100A, including anode region '488-110A, blockers '488-120A and '488-122A, and substrate '488-130A having cathode pattern region '488-132A. During electrolytic plating, the metal of anode region '488-110A (e.g., conductive metal, copper, etc) is electrodeposited onto cathode pattern region '488-132A. Anode region '488-110A is perforated by a plurality of openings to decrease the surface area of anode region '488-110A, and thus the relative amount of metal of anode region '488-110A available for electrodeposition onto cathode pattern region '488-132A. For example, where cathode pattern region '488-132A requires a greater amount of plated conductive metal (e.g., desired thickness of plated metal greater than 50 nm, 100 nm, 200 nm, 300 nm, 500 nm, surface area of cathode pattern is more than 50%, 60%, 70%, 80%, or 90% of region of substrate, etc), anode region '488-110A has relatively low density of perforations (e.g., less than 30%, 20%, or 10% surface area of region of anode has perforations, etc), such that the surface area of anode region '488-110A available for electrolytic plating (e.g., conductive metal available for electrodeposition) is proportional to the conductive metal desired to be plated to cathode pattern region '488-132A.

FIG. 7B depicts plating assembly '488-100B, including anode region '488-110B, blockers '488-120B and '488-122B, and substrate '488-130B having cathode pattern region '488-132B. Comparing cathode pattern region '488-132A of FIG. '488-1A and cathode pattern region '488-132B of FIG. '488-1B, cathode pattern region '488-132B has substantially less surface area (and thus need of conductor for electrolytic plating) than cathode pattern region '488-132A. Thus, anode region '488-110B will have a greater number of perforations, resulting in a lower surface area of anode region '488-110B corresponding to cathode pattern region '488-132B, such that the surface area of anode region '488-110B (and metal available for electrolytic plating) is proportional to the surface area of cathode region '488-132B (and conductive metal desired for plating).

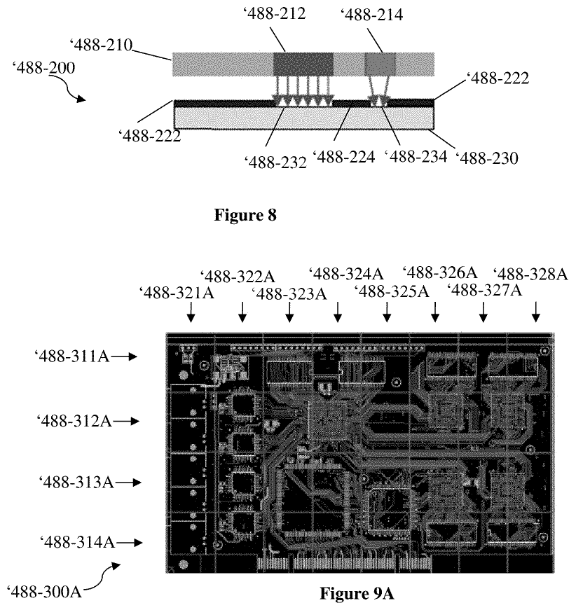

FIG. 8 depicts plating assembly '488-200, including anode '488-210 having anode region '488-212 and anode region '488-214, blockers '488-220, '488-222, and '488-224, and substrate '488-230 having cathode pattern regions '488-232 and '488-234. In this embodiment, cathode region '488-232 has greater surface area, and thus greater need for conductive metal for electrolytic plating, than cathode region '488-234. Correspondingly, anode region '488-212 has fewer perforations (e.g., openings, gaps, slits, holes, etc), and thus more surface area and metal available for electrolytic plating, than anode region '488-214. Notably, the size and dimension (e.g., shape, width, length, etc) of anode region '488-212 approximately mirrors the size and dimension of cathode pattern region '488-232. Likewise, the size and dimension of anode region '488-214 approximately mirrors the size and dimension of cathode pattern region '488-234.

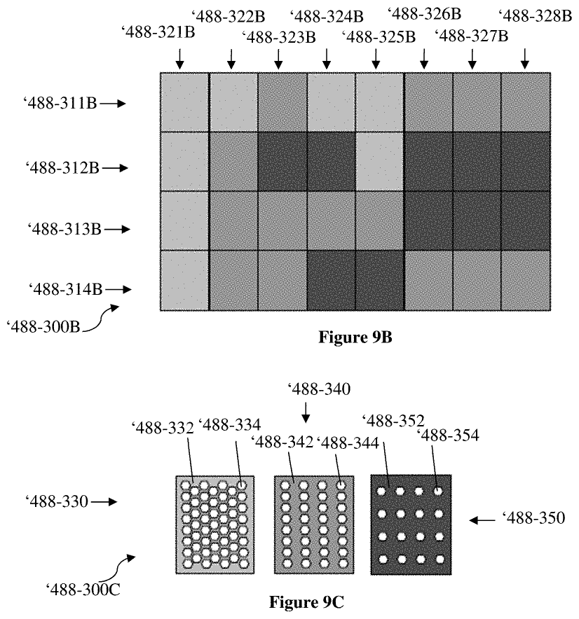

FIG. 9A depicts circuit board '488-300A divided into rows '488-311A, '488-312A, '488-313A, and '488-314A, and columns '488-321A, '488-322A, '488-323A, '488-324A, '488-325A, '488-326A, '488-327A, and '488-328A, for a total of 32 cells. Each of the 32 cells corresponds to a region of circuit board '488-300A having various cathode patterns with respective density of cathode pattern, or ratio of cathode pattern surface area to non-cathode pattern surface area in the cell. For example, the cells in column '488-321A have a lower density of cathode pattern than, for example, the cell at column '488-323A, row '488-311A. Likewise, the cell at column '488-323A, row '488-311A has lower density of cathode pattern than, for example, the cells in column '488-326A at rows '488-312A and '488-313A.

FIG. 9B depicts anode '488-300B divided into rows '488-311B, '488-312B, '488-313B, and '488-314B, and columns '488-321B, '488-322B, '488-323B, '488-324B, '488-325B, '488-326B, '488-327B, and '488-328B, for a total of 32 cells. Each of the 32 cells corresponds to a region of anode '488-300B with perforation patterns (e.g., holes, gaps, openings, channels, slits, combinations thereof, etc) resulting in a gradient of anode material surface area (e.g., density of perforations in each cell, ration of surface area of perforations in a cell to surface area of anode material in the cell, surface area of a cell less surface area of perforations in the cell, etc). For example, the cells in column '488-321B have a lower density of cathode pattern than, for example, the cell at column '488-323B, row '488-311B. Likewise, the cell at column '488-323B, row '488-311B has lower density of cathode pattern than, for example, the cells in column '488-326B at rows '488-312B and '488-313B. Further, the surface area of anode material in each cell of anode '488-300B is proportional to the density of cathode pattern in each cell of circuit board '488-300A.

Anode '488-300B is placed over circuit board '488-300A in an electrolyte bath for electrolytic plating of the conductor patterns on circuit board '488-300A. Anode '488-300B and circuit board '488-300A are aligned substantially parallel such that each cell of anode '488-300B is aligned (e.g., overlaps) with each corresponding cell of circuit board '488-300A. Such an assembly of circuit board '488-300A, with cells of carrying density of cathode pattern in conjunction with anode '488-300B, with cells of anode surface area proportional to the density of cathode pattern in respective cells of circuit board '488-300A, improves plating uniformity of conductor to cathode patterns of circuit board '488-300A, as well as reducing cost and waste of electrolytic plating materials.

FIG. 9C depicts array '488-300C of perforated anode regions '488-330, '488-340, and '488-350. Each anode region includes anode material '488-332, '488-342, and '488-352 (e.g., conductive metal, copper, etc), respectively, with each region having a pattern of perforations '488-334, '488-344, and '488-354 (hexagonal holes). The shade of each anode region corresponds with a pattern of perforations present in each cell of anode '488-300B. For example, anode region '488-330 is representative of a pattern in row '488-321B of anode '488-300B, anode region '488-340 is representative of a pattern in the cell at column '488-323B, row '488-311B, and anode region '488-350 is representative of a pattern in the cells in column '488-326B at rows '488-312B and '488-313B.

The following discussion provides many example embodiments of the inventive subject matter. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

In some embodiments, the numbers expressing quantities of ingredients, properties such as concentration, reaction conditions, and so forth, used to describe and claim certain embodiments of the invention are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

Unless the context dictates the contrary, all ranges set forth herein should be interpreted as being inclusive of their endpoints, and open-ended ranges should be interpreted to include only commercially practical values. Similarly, all lists of values should be considered as inclusive of intermediate values unless the context indicates the contrary.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A method of manufacturing a conductive layer, comprising:
forming a first surface topography on a first surface of a substrate by laminating a first layer of aluminum to the first surface of the substrate;
removing the first layer of aluminum from the substrate;
depositing a first catalyst over the first surface topography of the substrate;
forming a first seed layer over the first surface by electrochemical deposition;
forming a first plating resist layer over the first seed layer in a first negative pattern of at least a first portion of the conductive layer, forming a first conductor pattern;
depositing, by electrolytic deposition, the first portion of the conductive layer to the first seed layer in the first conductor pattern; and
removing the first plating resist layer and the portions of the first seed layer and the first catalyst covered by the first plating resist layer.

2. The method of claim 1, further comprising forming a second surface topography on a second surface of the substrate by laminating a second layer of aluminum to the second surface of the substrate.

3. The method of claim 2, wherein the step of forming the first surface topography and the second surface topography are at least partially simultaneous.

4. The method of claim 1, wherein a surface of the first layer of aluminum interfacing with the first surface of the substrate comprises the first surface topography.

5. The method of claim 1, wherein the first layer of aluminum is removed chemically or physically.

6. The method of claim 1, wherein laminating the first layer of aluminum to the substrate is by at least one of heat, pressure, or adhesion.

7. The method of claim 1, wherein the first surface topography comprises a laminate film.

8. The method of claim 1, wherein the first catalyst is deposited by at least one of an aqueous deposition process, a sputtering process, or a liquid coating process.

9. The method of claim 1, wherein the portions of the first catalyst covered by the first plating resist layer are removed chemically, mechanically, thermally, or photonically.

10. The method of claim 1, wherein the first seed layers a chemically etchable metal.

11. The method of claim 1, wherein the first seed layer is selected from the group consisting of copper, nickel, palladium, platinum, gold, and an alloy of one of these metals.

12. The method of claim 1, wherein the conductive layer is selected from the group consisting of copper, silver, palladium, platinum, gold, an alloy of one of these metals, and layers of at least two of these metals.

13. The method of claim 2, further comprising the steps of removing the second layer of aluminum from the substrate, depositing a second catalyst over the second surface topography of the substrate, forming a second seed layer over the second surface by electrochemical deposition, forming a second plating resist layer over the second seed layer in a second negative pattern of at least a second portion of the conductive layer, forming a second conductor pattern, depositing the second portion of the conductive layer to the second seed layer in the second conductor pattern, and removing the second plating resist layer and the portions of the second seed layer and the second catalyst covered by the second plating resist layer.

14. The method of claim 9, wherein the first and second surfaces of the substrate are on opposite sides of the substrate.

15. The method of claim 1, wherein the substrate is one of a porous dielectric, a semi-porous dielectric, or a non-porous dielectric.

16. The method of claim 1, wherein the first surface topography is a regular or random pattern of at least one of cones, spheroids, cylinders, cubes, tetrahedrons, pyramids, pits, ridges, crags, valleys, or waves.

17. The method of claim 1, wherein the first surface topography has a maximum roughness depth (Rmax) less than 15 microns, preferably less than 5.0 microns, more preferably less than 1.0 microns.

18. The method of claim 1, wherein the first surface topography has an arithmetic average roughness (Ra) less than 5 microns, preferably less than 1.0 microns, more preferably less than 0.5 micron.

19. The method of claim 1, wherein the first layer of aluminum further comprises a releasing treatment at an interface between the first layer of aluminum and the first surface of the substrate, wherein the releasing treatment comprises at least one of a silicon compound, a fluorine compound, or a mixture of thereof.

20. The method of claim 1, wherein the first layer of aluminum is at most 1000 microns thick.

21. A conductive layer manufactured by the process of claim 1.

22. A method of manufacturing a conductive layer, comprising:
forming a first surface topography on a first surface of a substrate by laminating a first layer of aluminum to the first surface of the substrate;
removing the first layer of aluminum from the substrate;
depositing a first catalyst over the first surface topography of the substrate;
forming a first dielectric layer over the first catalyst in a first negative pattern of at least a first portion of the conductive layer, forming a first conductor pattern; and
depositing the first portion of the conductive layer to the first catalyst in the first conductor pattern.

23. The method of claim 22, wherein the first dielectric layer is removed chemically, mechanically, thermally, photonically, or a combination of two or more thereof.

24. The method of claim 22, further comprising the step of removing wherein the step of removing the first dielectric layer and the first catalyst covered by the first dielectric, exposing a residue of the first catalyst.

25. The method of claim 22, further comprising forming a second surface topography on a second surface of the substrate by laminating a second layer of aluminum to the second surface of the substrate.

26. The method of claim 22, further comprising the steps of removing the second layer of aluminum from the substrate, depositing a second catalyst over the second surface topography of the substrate, forming a second dielectric layer over the second catalyst in a second negative pattern of at least a second portion of the conductive layer, depositing the second portion of the conductive layer to the second catalyst in the second negative pattern, and removing the second dielectric layer and portions of the second catalyst covered by the second dielectric layer.

27. A cladded laminate having a topography on a dielectric substrate, comprising:
a first aluminum film, wherein a surface of the first aluminum film comprises the topography; and
a second aluminum film, wherein a surface of the second aluminum film comprises the topography;
wherein the dielectric substrate is disposed between the surface of the first aluminum film and the surface of the second aluminum film, such that a surface of the dielectric substrate comprises the topography.

28. The cladded laminate of claim 27, wherein the topography is a regular or irregular pattern of at least one of cones, spheroids, cylinders, cubes, tetrahedrons, pyramids, pits, ridges, crags, valleys, or waves.

29. The cladded laminate of claim 27, wherein the cladded laminate further comprises resin and reinforcement.

30. The cladded laminate of claim 27, wherein the resin comprises at least one of epoxy, polyimide, cyanate ester, hydrocarbon, fluorinated hydrocarbon, bismaleimide triazine resin, or a combination of two or more thereof,

31. The cladded laminate of claim 27, wherein the reinforcement comprises at least one of fabric, paper, particle, chopped fiber, or a combination of two or more thereof.

32. The cladded laminate of claim 27, wherein the first aluminum film is less than 1000 microns thick.

33. The cladded laminate of claim 27, wherein the first aluminum film further comprises a releasing treatment at an interface between the first aluminum film and the first surface of the substrate, wherein the releasing treatment comprises at least one of a silicon compound, a fluorine compound, or a mixture of thereof.

34. The cladded laminate of claim 27, wherein the first surface topography has a Rmax less than 15 microns, preferably less than 7.5 microns, more preferably less than 5.0 microns.

35. The cladded laminate of claim 27, wherein the first surface topography has an arithmetic average roughness (Ra) less than 5 microns, preferably less than 1.0 microns, more preferably less than 0.5 micron.
